(19) United States
(12) Patent Application Publication
(10) Pub. No.: US 2014/0124254 A1
(43) Pub. Date: May 8, 2014

(54) NON-SOLDER MASK DEFINED COPPER PAD AND EMBEDDED COPPER PAD TO REDUCE PACKAGING SYSTEM HEIGHT

(71) Applicant: NVIDIA CORPORATION, Santa Clara, CA (US)

(72) Inventors: Leilei ZHANG, Sunnyvale, CA (US); Ron Boja, Gilroy, CA (US); Abraham F. YEE, Cupertino, CA (US); Zuhair BOKHAREY, Fremont, CA (US)

(73) Assignee: NVIDIA CORPORATION, Santa Clara, CA (US)

(21) Appl. No.: 13/669,289

(22) Filed: Nov. 5, 2012

(51) Int. Cl. H05K 1/18; H05K 3/30

(52) U.S. Cl. 174/260; 29/829

(57) ABSTRACT

Embodiments of the present invention provide a packaging system, which generally includes a substrate, a first electrical conductive pad and a second electrical conductive pad formed on a top surface of the substrate, and a mask section formed on the top surface of the substrate and disposed between the first electrical conductive pad and the second electrical conductive pad. The packaging system further includes a passive component mounted onto a top surface of the mask section, wherein a portion of a back surface of the passive component is in physical contact with the first electrical conductive pad and the second electrical conductive pad, respectively.

### BACKGROUND OF THE INVENTION

1. Field of the Invention

Embodiments of the present invention generally relate to an integrated circuit packaging system with passive components.

2. Description of the Related Art

Integrated circuits may be formed on semiconductor wafers made of materials such as silicon. The semiconductor wafers are processed to form various electronic devices. The wafers are diced into semiconductor chips (a chip is also known as a die), which may then be attached to a package substrate using a variety of known methods. The package substrate may then be attached to a printed circuit board (PCB) through solder balls to provide power and signals to and from the semiconductor chips.

The ever-decreasing size of electronic devices, such as handheld computers or cellular telephones, have driven the need for semiconductor device assemblies and packages with ever-decreasing profiles. Numerous techniques have been developed by the industry to reduce the total package height and footprint of the electronic components on the package. For example, one technique that has been proposed is to reduce the thickness of an active component (e.g., a die) which is disposed on the package substrate, thereby reducing the package height. Another technique used to reduce the footprint of the electronic components on the package is to mount a passive component (e.g., a capacitor) directly onto the package substrate, as opposed to the conventional approach where the passive component is mounted on the periphery of the package substrate and electrically connected to the package substrate through connecting wires.

FIG. 1 illustrates a schematic sectional view of a conventional packaging system 100 using two techniques mentioned above. As shown, an active component 112 is electrically connected to the conductive pads 114 embedded within a solder mask layer 104 by solder bumps 116. The solder mask layer 104 is formed on a package substrate 101 and covers the top surface of the package substrate 101 except for the region where a passive component 110 is located. The package substrate 101 is attached to a printed circuit board (PCB) 120 through solder balls 118. Conductive lines 122 (only one is shown), which may run through the package substrate 101, provide signals and/or power from the PCB 120 to the active component 112 through the conductive pads 114 and solder bumps 116. A pair of separate bond pads 102a, 102b may be formed at predetermined positions on the package substrate 101 and is exposed through the solder mask layer 104 covering the top surface 106 of the package substrate 101. Each of the exposed bond pads 102a, 102b is a so-called solder mask defined (SMD) bond pad whose periphery is respectively covered by the solder mask layer 104 and a solder mask section 107. With an appropriate amount of solder paste 108 being applied on the bond pads 102a, 102b, the edges of a passive component 110 can be bonded to the solder paste 108 and thus in electrical communication with the bond pads 102a, 102b through the solder paste 108. Similarly, conductive lines 124 (only one is shown), which form through the package substrate 101 and are in electrical communication with the PCB 120 through the solder balls 118, may provide signals and/or power from the PCB 120 to the passive component 110 through bond pads 102a, 102b and solder paste 108.

While the thickness of the active component 112 shown in FIG. 1 has been decreased to reduce the height “H₁” (from the top surface of the active component 112 to the bottom of the solder balls 118) of the package, the total package height “H₂” (from the top surface of the passive component 110 to the bottom of the solder balls 118) has not been reduced further due to the limited, fixed-size passive component 110 that is currently available in the market.

Therefore, there is a need in the art for a cost-effective packaging system having a reduced package height.

### SUMMARY OF THE INVENTION

One embodiment of the present invention provides a packaging system, which generally includes a substrate, a first electrical conductive pad and a second electrical conductive pad formed on a top surface of the substrate, and a mask section formed on the top surface of the substrate and disposed between the first electrical conductive pad and the second electrical conductive pad. The packaging system further includes a passive component mounted onto a top surface of the mask section, wherein a portion of a back surface of the passive component is in physical contact with the first electrical conductive pad and the second electrical conductive pad, respectively.

One advantage of the present invention is that the total height of the packaging system can be reduced by 25 μm or more by reducing the thickness of a mask section disposed underneath the passive component. Particularly, the top surface of the first and second electrical conductive pads is not covered by the mask section nor a solder mask layer that is formed surrounding the first and second electrical conductive pads, as opposed to existing packaging structure where the periphery of the first and second electrical conductive pads are covered by the solder mask section and the solder mask layer. The inventive passive component can be directly disposed on the top surface of the first and second electrical conductive pads, thereby reducing the total height of the packaging system. The reduced profile of the packaging system results in a thinner and lighter electronic device.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. In addition, the illustration in the appended drawings is not drawn to scale and is provided for illustration purpose.

FIG. 1 is a schematic cross-sectional view of a conventional package system.

FIG. 2A is a schematic top view of a portion of a packaging system showing an exemplary arrangement of a passive component with respect to a pair of bond pads and a solder mask section, according to one embodiment of the invention.

FIG. 2B is a cross-sectional view taken along line 2B-2B of FIG. 2A.

FIG. 2C is a cross-sectional of a portion of a packaging system according to another embodiment of the invention.

FIG. 3 is a cross-sectional of a portion of a packaging system according to another embodiment of the invention.

FIG. 4 illustrates an exemplary process sequence used to form a packaging system according to one embodiment of the invention.

FIG. 5 illustrates an exemplary process sequence used to form a packaging system according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide a reduced-height packaging system in which a solder mask section disposed underneath a passive component is reduced in thickness. In various embodiments, the passive component is in direct physical contact with a portion of a pair of bond pads located adjacent to the solder mask section. The solder mask section is formed on a package substrate and is sandwiched between the pair of bond pads (formed on the package substrate). The opposing side of each of the bond pads facing away from the solder mask section may be in physical contact with a solder mask layer. The solder mask layer covers the top surface of the package substrate with an opening through which the bond pads are exposed. In certain embodiments, the pair of bond pads is embedded within the top surface of the package substrate to further reduce overall package profile. In such a case, the solder mask section disposed underneath the passive component can be removed. Details of the invention are discussed in greater detail below.

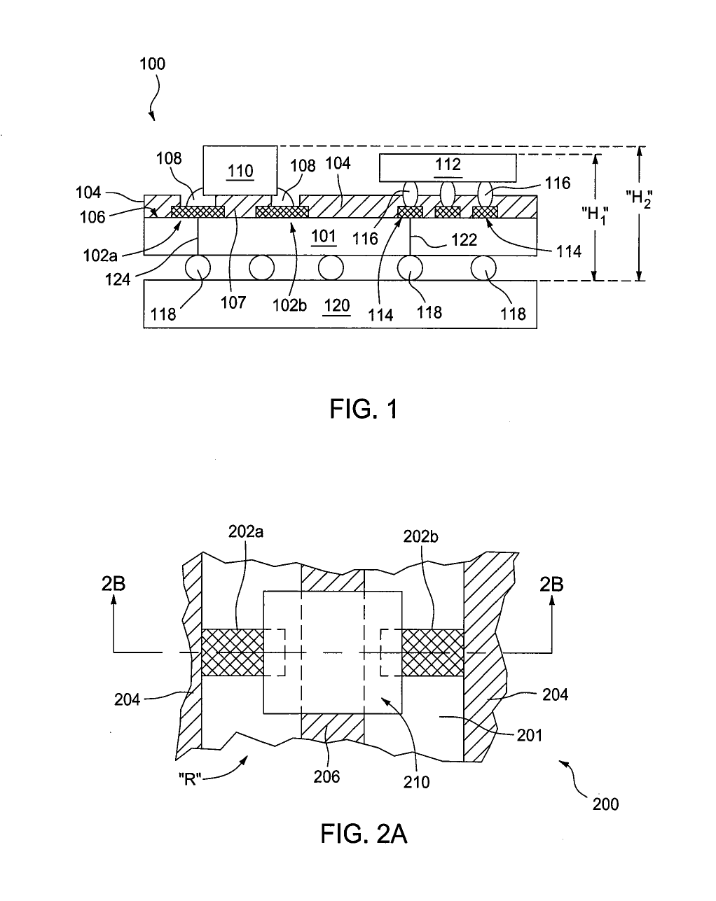

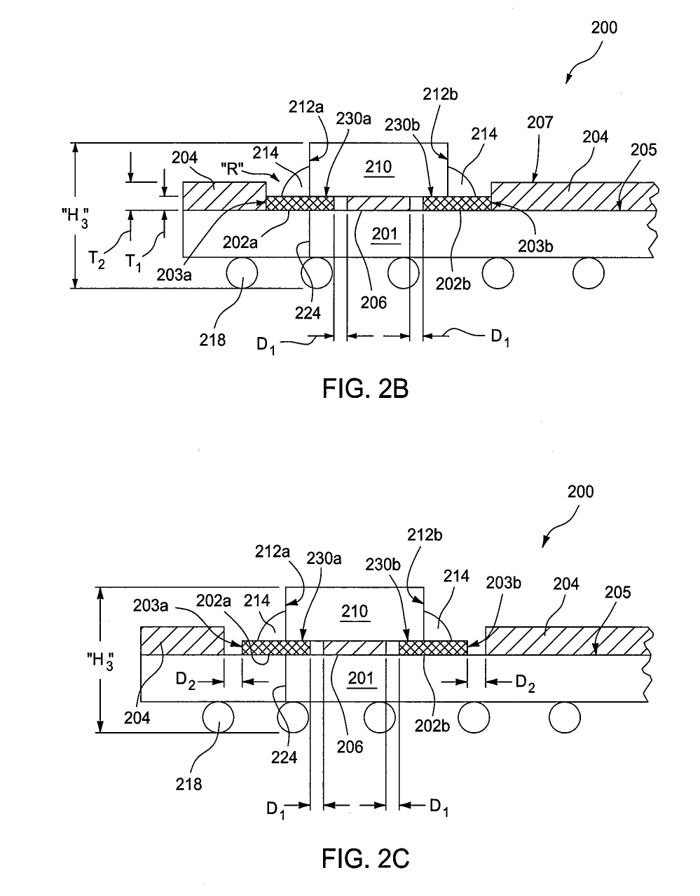

FIG. 2A is a schematic top view of a portion of a packaging system 200 showing an arrangement of a passive component with respect to a pair of bond pads and a solder mask section, according to one embodiment of the invention. FIG. 2B is a cross-sectional view taken along line 2B-2B of FIG. 2A. For ease of understanding, the active component and its associated elements as shown in FIG. 1 have been omitted. Refer to FIG. 2B, the packaging system 200 generally includes a package substrate 201 and a solder mask layer 204 covering a top surface 205 of the package substrate 201, with a region “R” of the package substrate 201 being exposed for accommodation of a passive component 210 and a pair of bond pads 202a, 202b. The passive component may be capacitors, resistors, transformers, etc. The pair of bond pads 202a, 202b is formed on the top surface 205 of the package substrate 201 and is properly spaced apart by a solder mask section 206. The solder mask layer 204 and solder mask section 206 may serve as a protective layer providing chemical and abrasion resistance to the package substrate 201. The solder mask layer 204 and solder mask section 206 also provide electrical isolation of the package substrate 201 and prevent moisture and contamination from accumulating on all non-electrode areas. While the region “R” is shown as square-like in FIG. 2A, it should be noted that the square-like region is used merely for illustrative purpose since the shape and size of the exposed region “R” may vary depending upon the pattern of the mask that is used to form the solder mask layer 204. It is also understood that while only a passive component and a pair of bond pads are shown, various numbers of passive components and bond pads may be formed on the package substrate depending upon the application.

In the embodiment shown in FIG. 2B, each of the bond pads 202a, 202b is in physical contact with the solder mask layer 204 by respective side 203a, 203b, respectively. As only one side of the bond pads 202a, 202b is in contact with the solder mask layer 204, the resulting bond pads 202a, 202b may be referred to as a half non-solder mask defined (NHSMD) bond pad, as opposed to a conventional solder mask defined (SMD) bond pad whose periphery is covered by the solder mask layer, or a non-solder mask defined (NSMD) bond pad which is completely free from contacting the solder mask layer. Having one side of bond pads 202a, 202b contacted the solder mask layer 204 is believed to be able to prevent potential pad lifting with the solder paste 214 and the associated shrinkage issues which may occur solidification of the solder paste 214. In an alternative embodiment, shown in FIG. 2C, sides 203a, 203b of the bond pads 202a, 202b are not in physical contact with the solder mask layer 204, leaving a clearance or a space having a distance “D₂” between the solder mask layer 204 and the bond pad 202a or 202b. The distance “D₂” between the solder mask layer 204 and the bond pad 202a or 202b may be between about 0 μm and about 100 μm, for example, about 50 μm.

In the embodiments of FIGS. 2B and 2C, the solder mask section 206 is formed on the top surface 205 of the package substrate 201 and is sandwiched between the bond pads 202a, 202b. The solder mask section 206 may be separated from the bond pads 202a, 202b by a distance “D₁”. That is, the solder mask section 206 does not extend to or cover the top surface of the bond pads 202a, 202b at the periphery. The distance “D₁” between the solder mask section 206 and the bond pad 202a or 202b may be between about 0 μm and about 100 μm, for example, about 50 μm. It is contemplated that the distance “D₁” may be minimized or eliminated so long as the thermal expansion differences between the solder mask section 206 and bond pads 202a, 202b are properly adjusted to avoid possible damage to the packaging structure.

The passive component 210 is disposed directly on the solder mask section 206, with its back surface on two opposing sides 212a, 212b in physical contact with the top surface 230a, 230b of the bond pads 202a, 202b, respectively. The passive component 210 is attached to the bond pads 202a, 202b through the use of a solder paste 214 or any suitable technique so that the passive component 210 is in electrical communication with the bond pads 202a, 202b, and thus in electrical communication with the underlying PCB (omitted) attached to the package substrate 201 through conductive lines 224 (only one is shown) and solder balls 218.

The solder mask section 206 may have the same height as the bond pads 202a, 202b. Taking the embodiment shown in FIG. 2B as an example, the bond pads 202a, 202b may have a thickness “T₁” of about 10 μm to about 30 μm, such as about 18 μm. The solder mask layer 204 may have a thickness “T₂” of about 25 μm to about 55 μm, such as about 40 μm. The solder mask layer 204 and the solder mask section 206 may be made of a polymer with high fluidity, for example, an epoxy resin or a polyester resin. As will be discussed later, the solder mask section 206 and the solder mask layer 204 may be formed by a single deposition process using various masking and/or etching techniques, or by two deposition processes in sequence with different masking approaches. Unlike the conventional packaging structure where the periphery of the bond pads 102a, 102b are covered by the solder mask layer 104 and the solder mask section 107 (FIG. 1), the inventive solder mask section 206 is reduced in thickness and does not cover the top surface of the bond pads 202a, 202b. Therefore, the passive component 210 is able to be directly disposed on the top surface of the bond pads 202a, 202b at the periphery, lowering the height of the passive component 210 from a position substantially above a top surface 207 of the solder mask layer 204 to a lowered position below the top surface 207 of the solder mask layer 204. It has been proved that the total height “H₃” of the packaging system 200 can be reduced, which is about a 25 μm thickness reduction as compared to the conventional packaging structure.

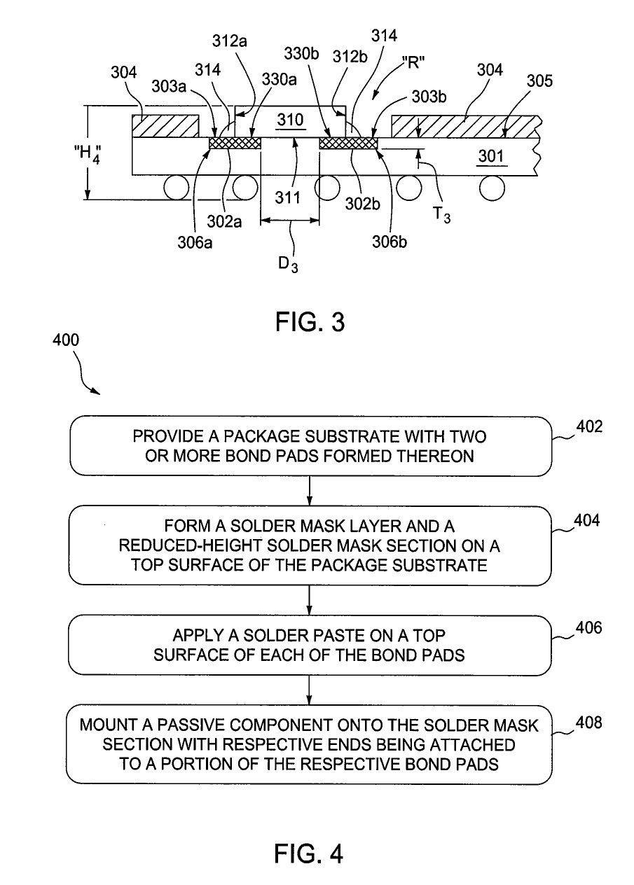

FIG. 3 is a schematic cross-sectional view of a packaging system 300 showing an arrangement of a passive component with respect to a pair of bond pads and a solder mask layer, according to another embodiment of the invention. Similarly, the active component and its associated elements as shown in FIG. 1 have been omitted for ease of understanding. Generally, the packaging system 300 is similar to the embodiments shown in FIGS. 2B and 2C except that bond pads 302a, 302b are embedded within the package substrate 301. As shown, the packaging system 300 includes a package substrate 301 and a solder mask layer 304 covering a top surface 305 of the package substrate 301, with a region “R” of the package substrate 301 being exposed for accommodation of a passive component 310 and a pair of bond pads 302a, 302b. Particularly, the pair of bond pads 302a, 302b is positioned within a cavity 306a, 306b, respectively, formed in the top surface 305 of the package substrate 301. The bond pads 302a, 302b may be spared apart at a distance “D₃” of about 5 μm to about 60 μm. The cavities 306a, 306b can be formed by any suitable process known in the art, such as wet or dry etching process. The cavities 306a, 306b may be formed at a desired depth in the package substrate 301. In one example, the cavities 306a, 306b may have a thickness “T₃” of about 10 μm to about 30 μm, such as about 20 μm. The top surface 303a, 303b of the bond pads 302a, 302b may be flush with or slightly above the top surface 305 of the package substrate 301.

In this embodiment, the solder mask section, shown and described in the embodiments of FIGS. 2B and 2C, is removed. The passive component 310 is bonded to the bond pads 302a, 302b through a solder paste 314, with respective back surface 330a, 330b on two opposing sides 312a, 312b in direct physical contact with the bond pads 302a, 302b, respectively. In other words, the bottom surface 311 of the passive component 310 and the top surface 305 of the package substrate 301 are at the same elevation. Since the solder mask section is entirely removed and the bond pads 302a, 302b are embedded within the package substrate 301, the total height “H₄” of the packaging system 300 can be further reduced, which is about a 45 μm thickness reduction as compared to the conventional packaging structure.

FIG. 4 illustrates an exemplary process sequence 400 used to form a packaging system, such as packaging system 200 of FIGS. 2B and 2C, according to one embodiment of the invention. It should be noted that the number and sequence of steps illustrated in FIG. 4 are not intended to be limiting as to the scope of the invention described herein, since one or more steps may be added, deleted and/or reordered without deviating from the basic scope of the invention.

The process sequence 400 starts at step 402 by providing a package substrate with two or more bond pads formed thereon, such as the package substrate 201 and a pair of bond pads 202a, 202b shown in FIGS. 2B and 2C. The bond pads may be formed on the package substrate by any suitable deposition process known in the art, such as an electroplating process or a physical vapor deposition (PVD) process. The bond pads may be made of any electrical conductive material such as copper, aluminum, gold, silver, or alloys of two or more elements. The package substrate may be a laminate substrate comprised of a stack of insulative layers. The package substrate may have conductive lines (such as conductive lines 224 shown in FIGS. 2B and 2C) embedded or formed therein. The conductive lines may include a plurality of horizontally oriented wires or vertically oriented vias running within the package substrate to provide power, ground and/or input/output (I/O) signal interconnections between the passive/active components and a printed circuit board (PCB). The term “horizontal” as used herein is defined as a plane parallel to the plane or surface of the package substrate, regardless of its orientation. Also, the term “vertical” refers to a direction perpendicular to horizontal as defined herein. The package substrate therefore provides the packaging system with structural rigidity as well as an electrical interface for routing input and output signals and power between the passive/active components and the PCB. Suitable materials that may be used to make the package substrate include, but are not limited to FR-2 and FR-4, which are traditional epoxy-based laminates, and the resin-based Bismaleimide-Triazine (BT) from Mitsubishi Gas and Chemical. FR-2 is a synthetic resin bonded paper having a thermal conductivity in the range of about 0.2 W/(K-m). FR-4 is a woven fiberglass cloth with an epoxy resin binder that has a thermal conductivity in the range of about 0.35 W/(K-m). BT/epoxy laminate packaging substrates also have a thermal conductivity in the range of about 0.35 W/(K-m). Other suitably rigid, electrically isolating, and thermally insulating materials that have a thermal conductivity of less than about 0.5 W/(K-m) may also be used.

In step 404, a solder mask layer (such as the solder mask layer 204 shown in FIGS. 2B and 2C) and a reduced-height solder mask section (such as the solder mask section 206 shown in FIGS. 2B and 2C) are formed on a top surface of the package substrate. Various approaches can be used to obtain the solder mask section at a reduced thickness. For example, in one embodiment the solder mask layer the solder mask section may be deposited using a mask to cover up areas where the bond pads are located. In cases where two bond pads are formed in a given region, a mask with three linear apertures may be used during a single deposition step to form two outer sections (i.e., the solder mask layer 204) and one middle section (i.e., the solder mask section 206) located between the two outer sections. Once the desired thickness of the two outer sections has been reached, an etching process is then performed to etch back the middle section, resulting in the solder mask section at a reduced thickness. Alternatively, two deposition steps may be performed by depositing a first section (i.e., the solder mask layer 204) on the package substrate. The first section is deposited by covering up a pre-determined region with a mask, i.e., covering region where the bond pads and the solder mask section are located or to be formed. Once the desired thickness of the first section has been reached, depositing a second section (i.e., the solder mask section 206) with the first section and bond pads being covered by a second mask until the desired thickness of the second section is reached. In either case, the solder mask section and the solder mask layer are formed in a manner that one side of each of the bond pads is in physical contact with the solder mask layer as shown in FIG. 2B, or each of the bond pads is free from contacting the solder mask layer and the solder mask section that is formed sandwiched between the bond pads, as shown in FIG. 2C.

If desired, the bond pads may be formed after the solder mask section and solder mask layer have been deposited on the package substrate.

In step 406, a solder paste (such as the solder paste 214 shown in FIGS. 2B and 2C) is applied on the top surface of each of the bond pads. The solder paste is configured to bond a subsequently formed passive component to the bond pads.

In step 408, a passive component is mounted onto the solder mask section with respective ends being attached to the respective bond pads. The passive component may be connected to the bond pads through a solder paste. In one embodiment, the back surface on two opposing sides of the passive component is in physical contact with the top surface of the respective bond pads at the periphery. The back surface of the passive component is therefore at the same elevation as the top surface of the solder mask section and the top surface of the bond pads. As a result, a portion of the packaging system as shown in FIGS. 2B and 2C is obtained.

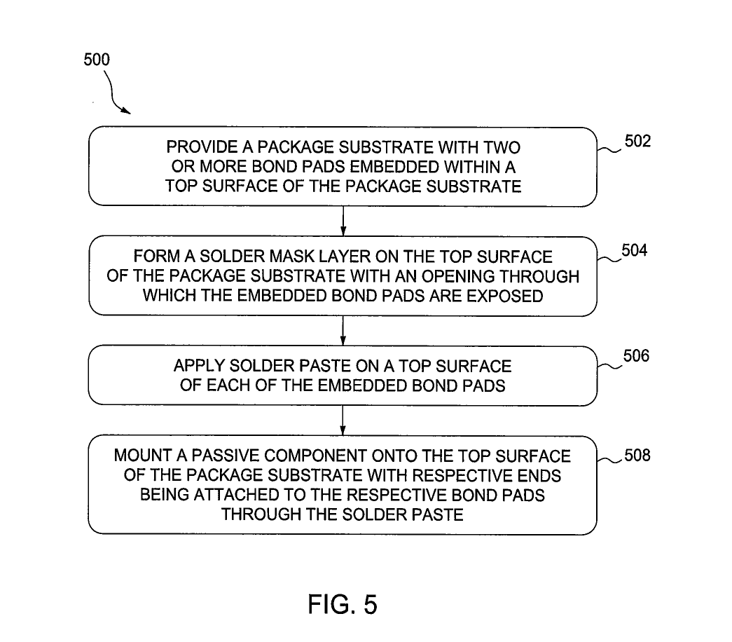

FIG. 5 illustrates an exemplary process sequence 500 used to form a packaging system, such as packaging system 300 of FIG. 3. It should be noted that the number and sequence of steps illustrated in FIG. 5 are not intended to be limiting as to the scope of the invention described herein, since one or more steps may be added, deleted and/or reordered without deviating from the basic scope of the invention.

The process sequence 500 starts at step 502 by providing a package substrate with two or more bond pads embedded therein, such as the package substrate 301 and bond pads 302a, 302b shown in FIG. 3. The embedded bond pads may be formed by any suitable technique, for example by using a wet or dry etching process to form cavities in the top surface of the package substrate, and filling the cavities with the electrical conductive material such as copper, aluminum, gold, silver, or alloys of two or more elements. The embedded bond pads may be flush with or slightly above the top surface of the package substrate as shown in FIG. 3.

In step 504, a solder mask layer (such as the solder mask layer 304 shown in FIGS. 3) is formed on a top surface of the package substrate with an opening through which the embedded bond pads are exposed. The opening has a size capable of accommodating a subsequently formed passive component. The solder mask layer may be formed by any suitable masking and deposition process similar to those discussed above with respect to step 404.

In step 506, a solder paste (such as the solder paste 314 shown in FIG. 3) is applied on the top surface of each of the embedded bond pads. The solder paste is configured to bond a subsequently formed passive component to the embedded bond pads.

In step 508, a passive component is mounted onto the top surface of the package substrate, with respective ends being attached respectively to the respective bond pads through the solder paste. In one embodiment, the back surface on two opposing sides of the passive component is in physical contact with a portion of the top surface of the respective bond pads. The back surface of the passive component is therefore at the same elevation as the top surface of the solder mask section and the top surface of the bond pads. As a result, a portion of the packaging system as shown in FIG. 3 is obtained.

In sum, embodiments of the invention provide various advantageous over prior art packaging structures, such as enabling overall thickness reduction of the package system by reducing the thickness of a solder mask section disposed underneath a passive component. The solder mask section is formed on a package substrate and is sandwiched between a pair of bond pads (formed on the package substrate). The height of the solder mask section is reduced to an extent that the passive component can be in direct physical contact with a portion of a pair of bond pads. Unlike the conventional packaging structure where the periphery of the bond pads is covered by the solder mask layer, the inventive solder mask section does not cover the top surface of the bond pads. Therefore, the passive component can be directly disposed on the top surface of the bond pads, thereby reducing the total height of the packaging system. In certain embodiments, the solder mask section disposed underneath the passive component is entirely removed so that the back surface on two opposing sides of the passive component can be in physical contact with the top surface of the respective bond pads embedded within the package substrate. As a result, the total height of the packaging system is further reduced.

While the foregoing is directed to embodiments of the present invention, other and further embodiments of the invention may be devised without departing from the basic scope thereof. The scope of the different embodiments is determined by the claims that follow.

1. A packaging system, comprising:
a substrate;
a first electrical conductive pad and a second electrical conductive pad, the first electrical conductive pad and the second electrical conductive pad being formed on a top surface of the substrate;
a mask section formed on the top surface of the substrate, the mask section being disposed between the first electrical conductive pad and the second electrical conductive pad; and
a passive component mounted onto a top surface of the mask section,
wherein a portion of a back surface of the passive component is in physical contact with the first electrical conductive pad and the second electrical conductive pad, respectively.

2. The packaging system of claim 1, wherein the mask section is separated from the first electrical conductive pad and the second electrical conductive pad by a distance.

3. The packaging system of claim 1, wherein a peripheral region of the back surface on opposing sides of the passive component is in physical contact with a top surface of the first electrical conductive pad and a top surface of the second electrical conductive pad, respectively.

4. The packaging system of claim 1, wherein the top surface of the mask section is at the same height as a top surface of the first electrical conductive pad and a top surface of the second electrical conductive pad.

5. The packaging system of claim 1, further comprising:
a mask layer covering the top surface of the substrate, wherein the mask layer is formed with an opening through which the mask section, the first electrical conductive pad, and the second electrical conductive pad are exposed.

6. The packaging system of claim 5, wherein the top surface of the mask section is at a height relatively lower than a top surface of the mask layer.

7. The packaging system of claim 5, wherein a side of the first electrical conductive pad facing away from the mask section is in physical contact with the mask layer, and a side of the second electrical conductive pad facing away from the mask section is in physical contact with the mask layer.

8. The packaging system of claim 5, wherein the mask section and the mask layer are made of the same material.

9. The packaging system of claim 8, wherein the mask section and the mask layer comprises a polymer material.

10. The packaging system of claim 5, wherein the first electrical conductive pad and the second electrical conductive pad are free from contacting the mask layer.

11. A packaging system, comprising:
a substrate;
a first electrical conductive pad and a second electrical conductive pad, the first electrical conductive pad and the second electrical conductive pad are embedded within a top surface of the substrate;
a passive component mounted onto the top surface of the substrate,
wherein a portion of a back surface of the passive component is in physical contact with the first electrical conductive pad and the second electrical conductive pad, respectively.

12. The packaging system of claim 11, wherein the first electrical conductive pad and the second electrical conductive pad are separated by a distance.

13. The packaging system of claim 11, wherein a top surface of the first electrical conductive pad and a top surface of the second electrical conductive pad are flush with or slightly above the top surface of the substrate.

14. The packaging system of claim 11, wherein a peripheral region of the back surface on opposing sides of the passive component is in physical contact with a top surface of the first electrical conductive pad and a top surface of the second electrical conductive pad, respectively.

15. The packaging system of claim 11, further comprising:
a mask layer covering the top surface of the substrate, wherein the mask layer is formed with an opening through which the first electrical conductive pad and the second electrical conductive pad are exposed.

16. A method for manufacturing a packaging system, comprising:
providing a substrate having a first electrical conductive pad and a second electrical conductive pad, the first electrical conductive pad and the second electrical conductive pad being separated by a middle region;
forming a mask section at the middle region;
mounting a passive component onto a top surface of the mask section, wherein the passive component is configured such that a portion of a back surface of the passive component is in physical contact with the first electrical conductive pad and the second electrical conductive pad, respectively.

17. The method of claim 16, wherein first electrical conductive pad and the second electrical conductive pad are formed on the top surface of the substrate or embedded within the top surface of the substrate.

18. The method of claim 17, wherein a peripheral region of the back surface on opposing sides of the passive component is in physical contact with a top surface of the first electrical conductive pad and a top surface of the second electrical conductive pad, respectively.

19. The method of claim 16, further comprising:
forming a mask layer on the top surface of the substrate, wherein the mask layer is deposited in a manner that the first electrical conductive pad and the second electrical conductive pad are surrounded by the mask layer, wherein a top surface of the mask layer is at an elevation relatively higher than the top surface of the mask section.

20. The method of claim 19, wherein the mask layer is configured to be in physical contact with a side of the first electrical conductive pad facing away from the mask section and a side of the second electrical conductive pad facing away from the mask section.

21. The method of claim 19, wherein the mask layer is configured to be separated from a side of the first electrical conductive pad facing away from the mask section and a side of the second electrical conductive pad facing away from the mask section.
